(19) United States
(12) Patent Application Publication
(10) Pub. No.: US 2008/0203566 A1
(43) Pub. Date: Aug. 28, 2008

(54) Stress buffer layer for packaging process

(76) Inventor: Chao-Yuan Su, Hsin-Chu County (TW)

Correspondence Address: SLATER & MATSIL, L.L.P., 17950 PRESTON ROAD, SUITE 1000, DALLAS, TX, 75252, US

(21) Appl. No.: 11/711,333

(22) Filed: Feb. 27, 2007

(51) Int. Cl. H01L 23/48

(52) U.S. Cl. 257/738; 257/777; 257/E23.08

(57) ABSTRACT

A semiconductor package structure is provided. The semiconductor package structure includes a first module; a second module, wherein the first and the second modules each are selected from the group consisting essentially of a package substrate, a die and a package module; and an elastic die-attaching film having a hardness of less than about 150 MPa interposed between the first and the second modules.

### TECHNICAL FIELD

This invention relates generally to the packaging of semiconductor dies, and more particularly to the packaging materials and methods for reducing stresses in packages.

### BACKGROUND

The fabrication of modern circuits typically includes several steps. Integrated circuits are first fabricated on a semiconductor wafer, which contains multiple identical semiconductor chips (also referred to as dies in the packaging art), each comprising integrated circuits. The semiconductor dies are then sawed from the wafer and packaged. The packaging processes have two main purposes: to protect delicate semiconductor dies and to connect interior integrated circuits in the dies to exterior pins of the packages.

In conventional packaging processes, semiconductor dies are mounted on a package substrate using flip-chip bonding or wire bonding. An epoxy molding compound is interposed between dies and the package substrate, and between dies. The epoxy molding compound is used to prevent cracks from being formed in solder bumps or solder balls, wherein cracks are typically caused by thermal stresses.

The conventional packaging processes, however, suffer drawbacks. High stress is generated, which is partially induced by a high mismatch of the coefficients of thermal expansion (CTE) between silicon semiconductor dies and package substrates. The stress causes several major reliability concerns. First, the stress may incur delamination at the interfaces between the dies and the epoxy molding compounds, and between the epoxy molding compounds and the package substrates. Second, the stress impacts the reliability of low-k and extreme low-k materials in semiconductor dies. Third, the stress may cause performance shifts in some stress-sensitive circuits, such as analog circuits, including phase-locked loops, digital-to-analog converters, and analog-to-digital converters.

The epoxy molding compounds currently used cannot provide adequate protection for the packages. In typical processes, the epoxy molding compounds are dispensed in the form of a liquid. Curing processes are then performed to solidify the epoxy molding compounds. After solidification, the epoxy molding compounds become rigid, and the stress generated in one portion of the package will be passed and dispersed throughout the epoxy molding compounds to other portions. As a result, delamination occurs at the weak points of the package.

Accordingly, new structures and/or packaging schemes for releasing the stress are needed in the art.

### SUMMARY OF THE INVENTION

In accordance with one aspect of the present invention, a semiconductor package structure includes a first module; a second module, wherein the first and the second modules each are selected from the group consisting essentially of a package substrate, a die and a package module; and an elastic die-attaching film interposed between the first and the second modules.

In accordance with another aspect of the present invention, a semiconductor package structure includes a package substrate having a plurality of bumps attached thereon; a first die having a first surface and a second surface opposite the first surface, wherein the second surface of the first die is bonded to the package substrate through the plurality of bumps; a second die having a first surface and a second surface opposite the first surface; and an elastic die-attaching film interposed between the first surface of the first die and the first surface of the second die, wherein the elastic die-attaching film is adapted to releasing stress and reliably bonding together the first and the second dies.

In accordance with yet another aspect of the present invention, a semiconductor package structure includes a first package substrate; a package module having a first surface, wherein the package module includes at least one die and a second package substrate therein; and a stack die module having a second surface facing the first surface. An elastic resin is interposed between the first surface and the second surface.

By using the elastic die-attaching film, the stresses in packages may be released.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a package structure including two dies bonded together through an elastic die-attaching film;

FIG. 2 illustrates a package including a package module and dies;

FIG. 3 illustrates a package module in a package structure, wherein the package module is attached to a package substrate; and

FIGS. 4 through 6 are cross-sectional views of intermediate stages in the manufacture of an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A semiconductor package structure including a novel die-attaching material is provided. The variations of the embodiments of the present invention are then discussed. Throughout the various views and illustrative embodiments of the present invention, like reference numbers are used to designate like elements

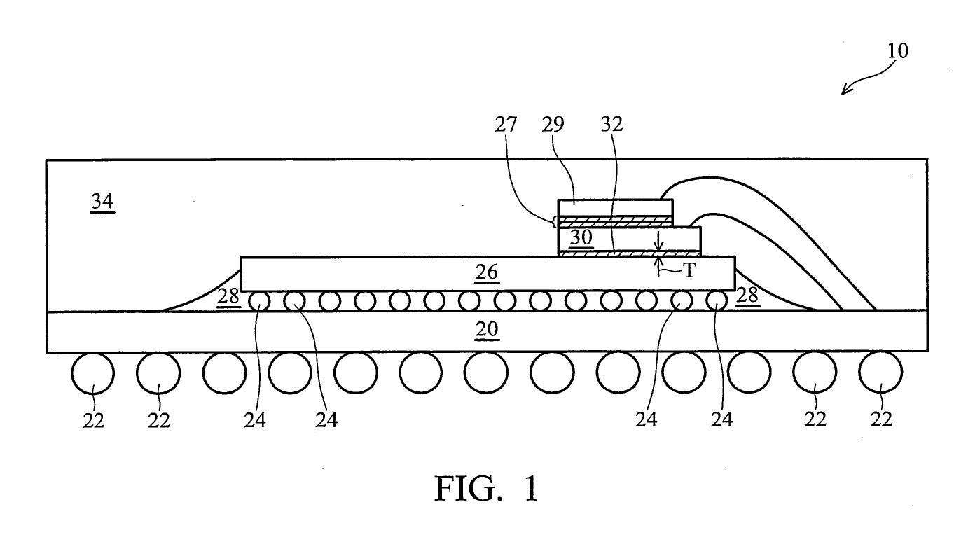

FIG. 1 illustrates package 10, which includes package substrate 20. On one side of package substrate 20, ball grid array (BGA) balls 22 are mounted. Bumps 24 are mounted on the opposite side of package substrate 20, connecting package substrate 20 to a first die 26. Bumps 24 may include commonly used bump materials such as eutectic materials or high-lead materials. Advantageously, the embodiments of the present invention release stresses in package 10. Therefore, bump materials prone to cracking, such as lead-free bump materials, may also be used. First die 26 is flip-chip bonded to package substrate 20. Underfill 28 is dispensed into the gaps between bumps 24.

Package 10 further includes a second die 30 over first die 26. Preferably, the bonding pads (not shown) in second die 30 face upwards, and are wire-bonded to package substrate 20. Second die 30 is attached to the die 26 through elastic die-attaching film 32.

In the preferred embodiment, elastic die-attaching film 32 includes a resin, such as thermal-set resin, polymers, epoxy resins, phenol hardenner, resin bases, hybrid resin, rubbers, and combinations thereof, and hence is alternatively referred to as resin-containing die attaching film 32. A filler material is included in elastic die-attaching film 32. The filler material preferably contains silicon, which may be in the form of silicon oxide. Other commonly used filler materials, such as SiO₂ and spherical silica may also be used. The thermal expansion coefficient of elastic die-attaching film 32 is preferably between about 50 parts per million (ppm) and about 1000 ppm.

Being elastic, elastic die-attaching film 32 has the function of absorbing, or in other words, releasing, stress. If one part of package 10, for example, first die 26, has a high stress, the stress is transferred to elastic die-attaching film 32. Elastic die-attaching film 32 thus releases stress by accordingly changing its shape. One skilled in the art will realize that the ability of elastic die-attaching film 32 to release stress is related to its hardness. If the hardness of elastic die-attaching film 32 is too high, its function of releasing stress is compromised by limiting its ability to accommodatingly change its shape. Conversely, if the hardness is too low, the elastic die-attaching film 32 may not be able to reliably bond die 26 and second die 30 together without subjecting die 30 to shifts in position. Therefore, the hardness of elastic die-attaching film 32 has an optimum range, which may be affected by the sizes of dies 26 and 30. In an embodiment, the hardness is preferably between about 50 MPa and about 150 MPa, and more preferably between about 50 MPa and about 60 MPa. The first die 26 and second die 30 may comprise at least one low-k (k<3.3) or extreme low-k (k<2.8) dielectric layer in the corresponding interconnect structures. The reliability of low-k and extreme low-k materials can be improved by using the elastic die attaching film between the adjacent dies.

The thickness T of elastic die-attaching film 32 is preferably between about 50 cm and about 75 μm. Table 1 illustrates experiment results showing the relationship between the pass rates and the thicknesses of elastic die-attaching film 32:

TABLE 1

Thickness

| | 30 μm | 50 μm | 75 μm | 125 μm |
|---|---|---|---|---|
| Pass Rate | 85% | 100% | 100% | 90% |

wherein the pass rates indicate the percentage of samples passing the experiment with no function failure. In the experiment, samples having the structure shown in FIG. 1, including dies 26 and 30 (but not die 29), are formed. After exposing the samples to thermal cycles, the integrated circuits in the samples are tested. The results indicate that thickness T has an optimum range, in which the pass rate is 100 percent. Beyond the optimum range, the pass rate decreases. The optimum range of thickness T is between about 50 μm and about 75 μm. It is appreciated that the optimum range of thickness T is related to various factors, such as the hardness of elastic die-attaching film 32, the overlap area of dies 26 and 30, and the like. If these values are too much more or less than the typical dies, the optimum thickness may change. When thickness T increases, elastic die-attaching film 32 has a greater ability to release stress. The stability of the attachment between dies 26 and 30, however, is degraded. Conversely, when thickness T decreases, the stability of the attachment between dies 26 and 30 improves. However, elastic die-attaching film 32 will have a lesser ability to release stress. Overall, thickness T needs to be balanced between the requirements of the ability to release stress and the ability to attach together dies 26 and 30 in a stable manner. The appropriately necessary optimum range may be obtained through experiments.

In alternative embodiments, by using additional elastic die-attaching films, additional dies may be mounted either on first die 26 or on second die 30. FIG. 1 illustrates an exemplary embodiment, in which die 29 is mounted on die 30 through elastic die-attaching film 27. Furthermore, each of the elastic die-attaching films 27 and 32 may include a single layer or a composite layer of elastic materials, wherein each sub-layer of the composite layer has a different hardness from others. An exemplary multi-layer die attaching film 27 is also shown in FIG. 1.

Package 10 further includes insulating material 34, which encloses bumps, dies, wirings and elastic die-attaching films therein. Insulating material 34 may comprise a molding material, such as an epoxy molding compound, preferably having a hardness of about 100 MPa or greater.

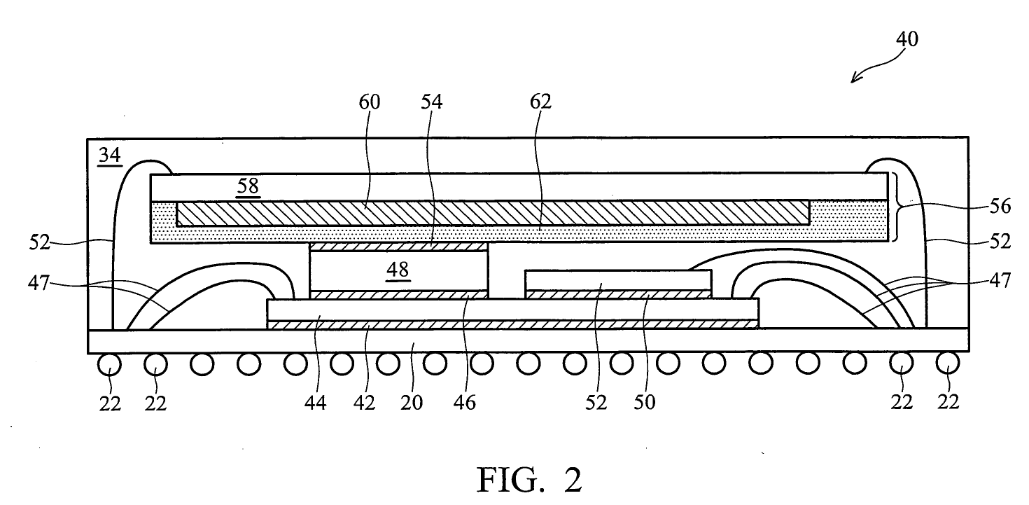

FIG. 2 illustrates a second embodiment of the present invention. Package 40 includes at least one die and at least one package module, and thus has a package-in-package structure. In this embodiment, wire bonding is used to attach dies to package substrate 20. BGA balls 22 are mounted on package substrate 20, and are electrically connected to the dies through the wire bonding. In an exemplary embodiment, a stack die structure, which includes a first die 44 and a second die 52, is packaged. The first die 44 is attached to package substrate 20 through elastic die-attaching film 42. The second die 52 is attached to first die 44 through elastic die-attaching film 50. First die 44 and second die 52 are bonded to package substrate 20 through wires 47. Each of the first die 44 and second die 52 may include digital circuits, analog circuits, and combinations thereof. As is known in the art, analog circuits are prone to the effect of stress, and their performance may shift under the stress. In an exemplary embodiment, first die 44 includes digital circuits, and second die 52 includes analog circuits, wherein the analog circuits may include phase-locked loops, digital-to-analog converters, analog-to-digital converters, regulators, filters, and combinations thereof.

Package 40 further comprises package module 56, which includes package substrate 58, die 60 and molding compound 62. Wires 53 connect package module 56 to package substrate 20. Spacer 48 is placed between package module 56 and the first die 44 in order to clear a space for the wiring of the first die 44 and the second die 52. Spacer 48 is attached to the first die 44 and package module 56 through elastic die-attaching films 46 and 54, respectfully. In an exemplary embodiment, die 60 is a memory die including memory circuits such as static random access memories.

Each of the above-referenced elastic die-attaching films 42, 46, 50 and 54 may be formed using essentially the same material as, and hence have same mechanical properties as, elastic die-attaching film 32 (refer to FIG. 1). Elastic die-attaching films 42, 46, 50 and 54 preferably include resin-containing die attaching materials. These elastic die-attaching films act as stress buffers, which release the stresses generated in local regions of package 40. As a result, the stress in package 40 is significantly reduced.

In a variation of the embodiment shown in FIG. 2, die 44 may be attached to package substrate 20 using flip-chip bonding through bumps (not shown). One skilled in the art will realize that more dies and package modules can be packaged in package 40, wherein each of the dies and package modules may be either attached to package substrate 20 directly, or attached to other dies or package modules.

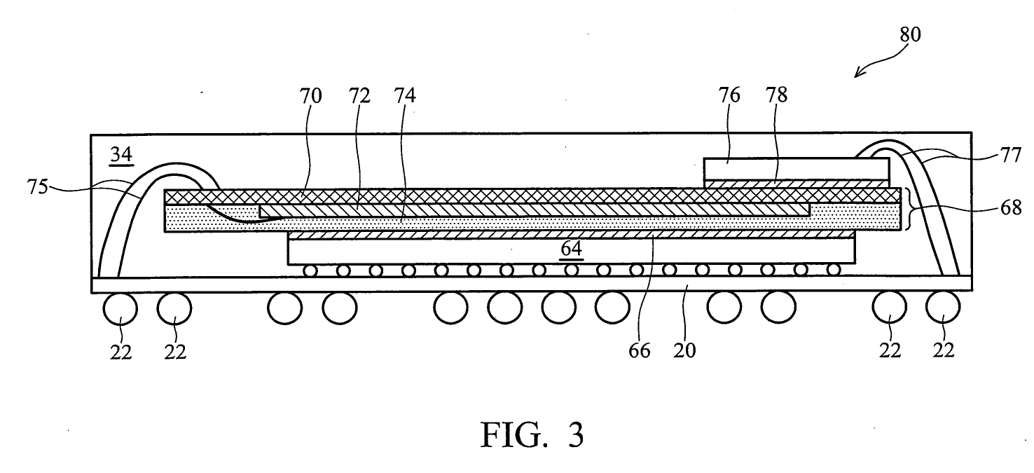

FIG. 3 illustrates a third embodiment of the present invention. Package 80 includes a first die 64 bonded to package substrate 20 through flip-chip bonding. BGA balls 22 are mounted on package substrate 20, and are electrically connected to the first die 64. BGA balls 22 further include portions connected to other dies and packages, such as package module 68 and die 76, through wire bonding.

Package module 68 includes package substrate 70, die 72 and molding compound 74. Wires 75 connect package module 68 to package substrate 20. In an exemplary embodiment, die 72 is a memory die including, for example, static random access memories. Package module 68 is attached to first die 64 through elastic die-attaching film 66.

A second die 76 is attached to package module 68 through elastic die-attaching film 78, wherein the second die 76 is bonded to package substrate 70 through wires 77. Similar to the second embodiment, each of the first die 64 and second die 76 may include digital circuits, analog circuits, and combinations thereof. In an exemplary embodiment, first die 64 includes digital circuits, and the second die 76 includes analog circuits.

In the second and the third embodiments, each of the elastic die-attaching films may include more than one elastic layers. In addition, insulating material 34, which are similar to the insulating material 34 shown in FIG. 1, are dispensed to protect dies, wirings, package modules, and the like.

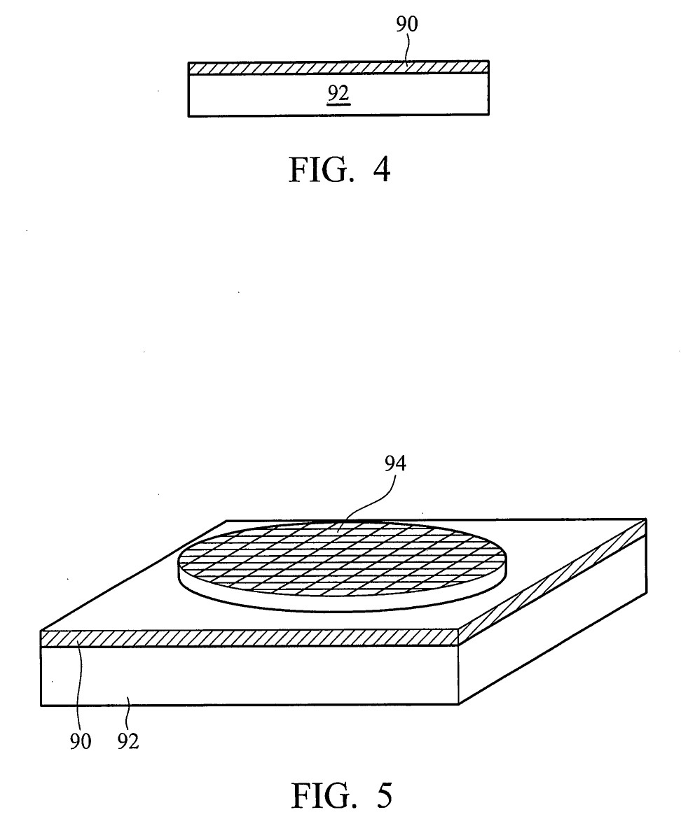

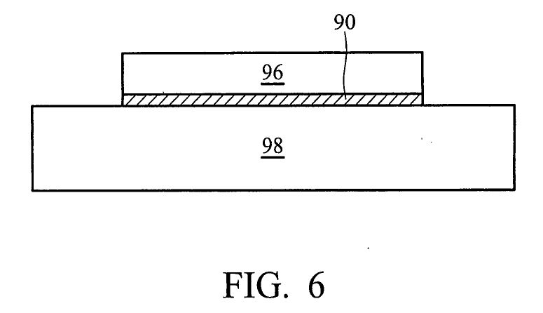

FIGS. 4 through 6 schematically illustrate a process for bonding two dies. Referring to FIG. 4, elastic die-attaching film 90, which is adhesive, is applied on die saw mounting tape 92. The thickness of elastic die-attaching film 90 is preferably essentially the same as discussed in the preceding paragraphs, for example, between about 50 μm and about 75 μm. In FIG. 5, wafer 94 is attached to the structure shown in FIG. 4, with elastic die-attaching film 90 attached to the backside of wafer 94. Wafer 94 is then sawed to separate the dies from the wafer, followed by removing die saw mounting tape 92 from dies. FIG. 6 illustrates one die 96, which includes elastic die-attaching film 90 on the back. Die 96 may then be bonded to other components, such as die 98, with elastic die-attaching film 90 therebetween. A thermal curing process is then performed to harden elastic die-attaching film 90. Advantageously, after the curing process, elastic die-attaching film 90 is still elastic.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor package structure comprising:
a first module;
a second module, wherein the first and the second modules each are selected from the group consisting essentially of a package substrate, a die and a package module; and
an elastic die-attaching film having a hardness of less than about 150 MPa interposed between the first and the second modules.

2. The semiconductor package structure of claim 1, wherein the hardness is between about 50 MPa and about 60 Mpa.

3. The semiconductor package structure of claim 1, wherein the elastic die-attaching film has a thickness of between about 50 μm and about 75 μm.

4. The semiconductor package structure of claim 1, wherein the elastic die-attaching film comprises a resin and a filler material, and wherein the filler material comprises silicon.

5. The semiconductor package structure of claim 1, wherein the first module is a package substrate, and the second module is a die, and wherein a back surface of the die is bonded to the package substrate through the elastic die-attaching film.

6. The semiconductor package structure of claim 1, wherein one of the first module and the second module comprises at least one low-k dielectric layer having a k value of less than about 3.3 therein.

7. The semiconductor package structure of claim 1, wherein the first module is a die, and the second module is selected from the group consisting essentially of a die and a package module.

8. The semiconductor package structure of claim 1, wherein at least one of the first and the second modules comprises a die, and wherein the die comprises an analog circuit.

9. The semiconductor package structure of claim 1 further comprising an insulating film enclosing the first module, the second module and the elastic die-attaching film.

10. A semiconductor package structure comprising:
a package substrate having a plurality of bumps attached thereon;
a first die having a first surface and a second surface opposite the first surface, wherein the second surface of the first die is bonded to the package substrate through the plurality of bumps;
a second die having a first surface and a second surface opposite the first surface; and
an elastic die-attaching film interposed between the first surface of the first die and the first surface of the second die, wherein the elastic die-attaching film is adapted to releasing stress and reliably bonding the first and the second dies.

11. The semiconductor package structure of claim 10, wherein the elastic die-attaching film has a hardness of less than about 150 MPa.

12. The semiconductor package structure of claim 10, wherein the elastic die-attaching film has a thickness of between about 50 μm and about 75 μm.

13. The semiconductor package structure of claim 10, wherein the elastic die-attaching film comprises a resin and a silicon-containing filler material.

14. The semiconductor package structure of claim 10, wherein the elastic die-attaching film comprises more than one sub layers.

15. The semiconductor package structure of claim 10 further comprising an additional die attached to the second surface of the second die through an additional elastic die-attaching film.

16. A semiconductor package structure comprising:
a first package substrate;
a package module having a first surface, wherein the package module includes at least one die and a second package substrate therein;
a stack die module having a second surface facing the first surface; and
an elastic resin interposed between the first surface and the second surface.

17. The semiconductor package structure of claim 16, wherein the elastic resin has a thickness of between about 50 μm and about 75 μm.

18. The semiconductor package structure of claim 16, wherein the elastic resin is a member of the group consisting of thermal-set resin, Polymer, Epoxy resin, Phenol harderner, Resin base, Hybrid resin, Rubber and combinations.

19. The semiconductor package structure of claim 16, wherein the stack die module comprises at least two dies, and a plurality of elastic resins adjoining the at least two dies.
